(19) United States
(12) Patent Application Publication
(10) Pub. No.: US 2024/0297124 A1
(43) Pub. Date: Sep. 5, 2024

(54) FLEXIBLE DESIGN AND PLACEMENT OF ALIGNMENT MARKS

(71) Applicant: Micron Technology, Inc., Boise, ID (US)

(72) Inventors: Shruthi Kumara Vadivel, Boise, ID (US); Harsh Narendrakumar Jain, Boise, ID (US); Lance David Williamson, Boise, ID (US); Kaveri Jain, Hyderabad (IN); Adam Lewis Olson, Boise, ID (US)

(21) Appl. No.: 18/593,504

(22) Filed: Mar. 1, 2024

Related U.S. Application Data
(60) Provisional application No. 63/449,863, filed on Mar. 3, 2023.

(51) Int. Cl. H01L 23/544; H01L 21/308

(52) U.S. Cl. CPC H01L 23/544; H01L 21/308; H01L 2223/54426

(57) ABSTRACT

A memory device can include a substrate and a first alignment mark embedded in the substrate. The first alignment mark can be configured to a reference for a patterned second masking layer which is different from a first masking layer deposited on the substrate, and onto which the second patterned masking layer is deposited. The first masking layer can be an opaque or semi-opaque sacrificial layer and a second alignment mark can comprise at least a portion of the first masking layer. A location of the second alignment mark can correspond to a particular structure location in the substrate. The patterned second masking layer can include an additional alignment mark that is spaced laterally apart from the second alignment mark and the patterned second masking layer can define one or more locations of one or more structural features in the substrate.

### PRIORITY APPLICATION

This application claims the benefit of priority to U.S. Provisional Application Ser. No. 63/449,863, filed Mar. 3, 2023, which is incorporated herein by reference in its entirety.

### TECHNICAL FIELD

The present disclosure relates to design and placement of alignment marks in semiconductor fabrication.

### BACKGROUND

In the field of semiconductor manufacturing, integrated circuits are manufactured in a sequence of steps. The steps can include depositing and patterning various materials on a semiconductor wafer to form devices such as transistors, contacts, and other circuit components. In order for the final device (e.g., an integrated circuit chip) to function properly, the components must be aligned on each layer of the wafer, or stated differently, the components on each layer must all “line up” with each other.

Alignment processes can include adjusting the wafer position relative to a photomask, or other mask, which can include a pattern etched into an opaque surface deposited on a surface of the wafer. Then, during subsequent steps in the fabrication process, the pattern can be used for etching or alignment of subsequent layers. Alignment marks can be used to calibrate and align patterns in the layers to be fabricated with other, previously-formed layers.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIGS. 1A-1D illustrate generally an example of a process flow that includes using topographical features in a hardmask layer that is disposed on a semiconductor substrate or die.

FIGS. 2A-2B illustrate generally an example of alignment marks buried in a hardmask layer that is provided on a surface of a die.

FIGS. 3A-3B illustrate generally an example that can include aligning topographical marks in a hardmask layer with reference marks in a substrate layer.

FIGS. 4A-4D illustrate generally an example of wafer fabrication using topographical marks and reference features in sacrificial areas of a die.

FIG. 5 illustrates generally an example of a top view of overlay marks relative to fields of a semiconductor array that can be separated by scribe lines.

FIG. 6 illustrates generally an example of a method that includes or uses one or more alignment features.

### DETAILED DESCRIPTION

During the semiconductor fabrication processes, patterns in various reticles or masking layers can be used to form or place circuit features on a semiconductor wafer or die. The circuit features can include components such as Field Effect Transistors (FETs), diodes, switches, contacts, or the like, that are built in or on the semiconductor wafer. Various marks or features can be used to calibrate and align patterns in one or more subsequent layers to other, earlier-formed layers, or to structures or features that comprise a portion of the die substrate itself.

Alignment in semiconductor fabrication is a process during which a scanner identifies alignment marks in or on a wafer to determine the wafer's position on a stage. Alignment is performed on the metrology side of the scanner before wafer exposure. For example, light can be projected onto the alignment marks, which can be gratings etched into a substrate, and diffracted light can be detected as a function of feature position in the wafer plane. Overlay refers to the accuracy of pattern placement (e.g., component or feature placement) on the wafer. Alignment marks can be read just before printing the subsequent or next layer of the wafer, and overlay is a measurement of how well the patterns align. Registration is a process in which overlay error can be measured, such as using targets on the current level or layer and targets on a reference level or layer, and corrective action can be taken. Thus, the alignment marks can be used in intermediate photolithography or processing steps to improve overlay accuracy, but such marks may be unneeded in a finished product.

The present inventors have recognized that a problem to be solved includes providing alignment marks efficiently and effectively such that scribe line width can be minimized. Scribe line width is generally decreasing node-over-node to increase yieldable area on a wafer, which in turn reduces or lowers the flexibility to include alignment marks or test structures in scribe lines and/or other portions of the die. Effective use of scribe space on the wafer can be important, for example, because of tightening requirements for overlays of higher-order signatures, which can use relatively more alignment marks to ensure proper alignment.

The present inventors have recognized that the problem can include providing alignment marks that are representative of features built into the die, for example, marks that are representative of a scribe line itself. For example, some dies can exhibit offset between scribe lines, or features indicating a scribe line, relative to features or components that are built into the die. The present systems and methods can be used to help reduce scribe line width and to provide better correspondence between alignment marks and particular die features by allowing for more flexible or ideal placement of alignment marks, such as for mapping an integrated circuit grid, without being limited to scribe line areas.

In an example, a semiconductor wafer can include a substrate and a first masking layer deposited on at least a portion of the substrate. The first masking layer can be a sacrificial layer that can be removed during a subsequent processing stage. A first reference alignment feature can comprise a portion of the first masking layer and can correspond to a particular structure or particular location in or on the substrate. The first reference alignment feature can, in an example, be a sacrificial alignment mark that can be removed during a subsequent processing stage. In an example, the structure with which the alignment feature can be aligned can be a circuit component such as a FET, a diode, a switch, a contact, or any other active or passive component or other feature.

In an example, the semiconductor wafer can include a second masking layer that is deposited on the first masking layer, or on at least a portion of the first masking layer. The second masking layer can cover at least a portion of the first reference alignment feature. In an example, the second masking layer can be patterned (e.g., using one or more patterning or etching operations) to include at least a second reference alignment feature. The second reference alignment feature can be spaced laterally apart from the first reference alignment feature. The second masking layer can be a sacrificial layer that can be removed during a subsequent processing stage, such as with or without removing the first masking layer.

The patterned second masking layer can indicate one or more locations of structural features built into another portion of the die that comprises the wafer. For example, the second reference alignment feature in the patterned second masking layer can indicate structural features of a memory circuit that comprises a portion of the die. The patterned second masking layer can be an overlay layer that is aligned with the substrate (and one or more features in or on the substrate) based on the first reference alignment feature. In an example, the second reference alignment feature can be a topographical alignment feature and the first reference alignment feature can be a non-topographical alignment feature such as can be embedded or buried in the substrate or the first masking layer. In an example, a topographical alignment feature includes a detectable, physical discontinuity such as a peak (e.g., a material buildup) or valley (e.g., a material void) in or on a portion of a layer, or in or on a surface of a substrate.

The semiconductor wafer can further include one or more scribe lines. In an example, a scribe line can intersect the substrate, the first masking layer, the patterned second masking layer, and the first reference alignment feature. Additionally, or alternatively, a scribe line can intersect the substrate, the first masking layer, and the patterned second masking layer without intersecting the first reference alignment feature.

A benefit of using alignment marks that are provided in sacrificial layers, or sacrificial alignment marks, includes allowing more physical area of a wafer to be used for placing overlay marks. Further, a location of a sacrificial alignment mark in a sacrificial layer above the substrate may not be restricted to locations that include scribe lines and therefore may not be subject to or impacted by decreasing scribe width, e.g., a width or thickness of the scribe lines. Another benefit can include increased flexibility of mark design. For example, the marks are not restricted to specific patterns imposed by array patterns or restricted to patterning design constraints of the die. For example, alignment marks on contact levels of the wafer are not restricted to requiring contact-design scribe marks. For levels or layers using opaque hardmasks, topographical marks can be used. In some examples, layer alignment based on topographical marks can be easier, for example, than using embedded marks because one or more other layers over an embedded mark may obstruct or impede identification of an embedded mark. In some examples, it can be desirable to use scribe lines or other sacrificial areas for alignment or registration marks to enable better metrology, however, in some applications, placement in a scribe line or other sacrificial area may not be possible due to patterning concerns. In other examples, where printing limitations are less of a concern, some scribe line area patterns can cause structural defects such as cracks (e.g., because of a larger surface area), corner effects due to a rectangular shape versus a contact shape, or the like. When marks are instead built on or in a sacrificial layer, scribe line or sacrificial areas can be patterned without concern for the same kinds of defects during subsequent processing.

Alignment marks can comprise various materials including metals like gold, copper, niobium, or the like or can be formed from materials such as amorphous carbon, an organo siloxane material, SiN, SiON, TiN, or tungsten. In an example, an alignment mark can be deposited on the surface of a mask layer or a substrate. In an example, an alignment mark can include a topographical feature such as an etched hole or depression in the mask or the substrate.

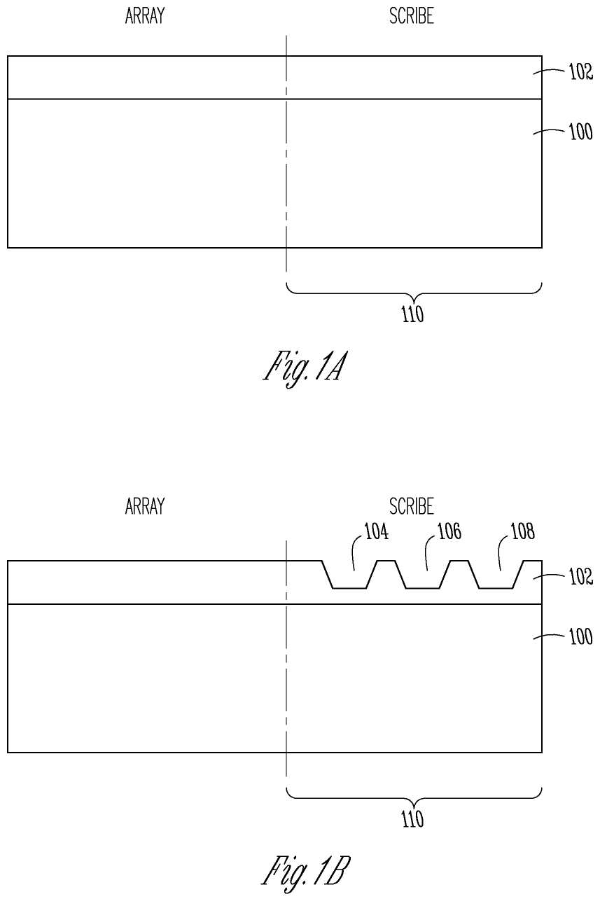

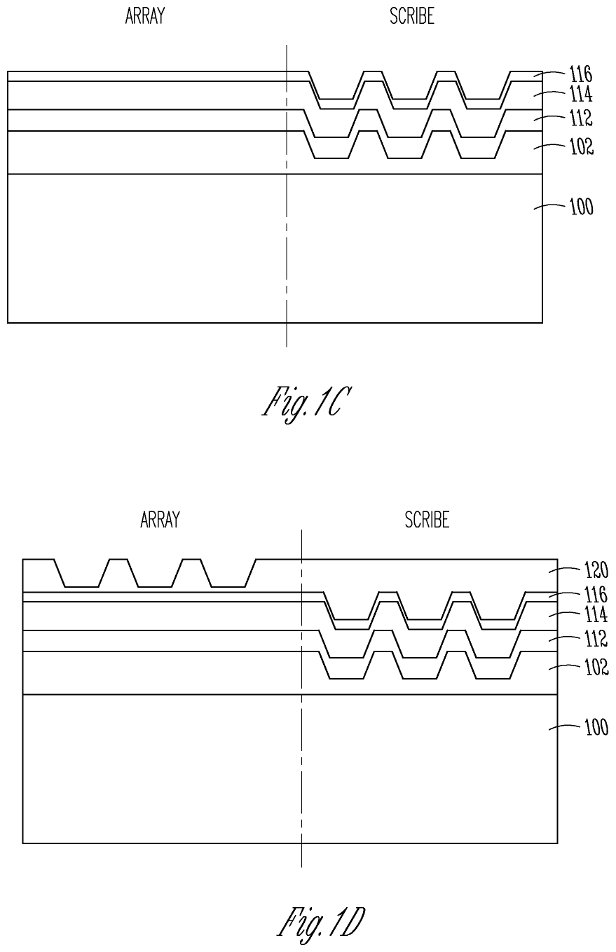

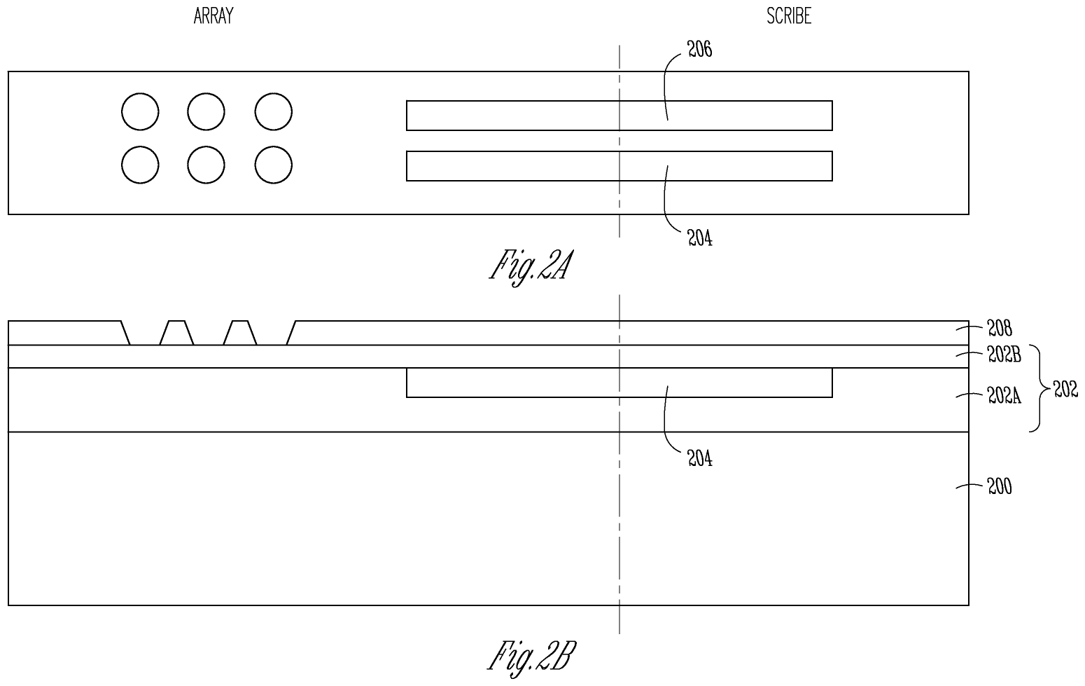

FIGS. 1A-1D illustrate generally an example of a process flow that includes using topographical features in a hardmask layer that is disposed on a semiconductor substrate or die. In an example, the hardmask layer comprises one or more sacrificial layers on the semiconductor substrate. The topographical features can, in an example, indicate a scribe line of the die, which in turn can indicate a portion of the die that may be sacrificed or removed by dicing.

FIG. 1A shows a cross-section of a substrate 100. In the illustrated example, a left side of the substrate 100 corresponds to a portion of a device array (e.g., comprising one or more functional devices or components formed in the substrate 100), and the right side of the substrate 100 corresponds to a portion of a scribe line 110. In a first step of the process flow, a first hardmask layer 102 can be deposited on top of or over a top surface of the substrate 100. In FIG. 1B, in a second step of the process flow, first topographical alignment marks 104, 106, and 108 can be patterned and etched into the first hardmask layer 102. In the illustrated example, the first topographical alignment marks 104, 106, and/or 108 are disposed in the area occupied by the scribe line 110. The alignment marks may be disposed inside the scribe line 110, for example, to help maximize an amount of area of the die that is designated for functional components.

In FIG. 1C, one or more other layers can be deposited, such as including a second hardmask layer 114 and/or film layers 112, 116, on or over the first hardmask layer 102 (collectively, “the additional layers”). The topographical alignment marks 104, 106, 108 can propagate up through the additional layers such that a top surface of the additional layers includes topographical alignment marks that correspond to the first topographical alignment marks 104, 106, and 108 formed in the first hardmask layer 102.

In an example, a resist layer 120 can be deposited or applied on the hardmask stack comprising the first and second hardmask layers 102 and 114, and the film layers 112, 116. The resist layer 120 can be patterned and used, for example, in subsequent processing steps for etching the substrate 100 and one or more layers disposed thereon. In an example, features in the resist layer 120 can be defined or positioned based on the location of the topographical features in the top-most layer (e.g., the film layer 116 in the illustrated example). In an example, the first topographical alignment marks 104, 106, and 108 can be protected by the resist layer 120 from an etchant or from other photolithographic processes and, accordingly, artifacts of the alignment marks 104, 106, and 108 may not be transferred to the substrate 100.

FIGS. 1B-1C illustrate that the first topographical alignment marks 104, 106, and 108 are formed in an area of the die corresponding to the scribe line 110, but topographical alignment marks can similarly be formed in the first hardmask layer 102, such as in any area or portion of the die. For example, topographical alignment marks or features can be provided over a functional area of the die. In an example, the first hardmask layer 102 and/or any of the additional layers may be an opaque or semi-opaque (e.g., to particular wavelengths of light) layer that at least partially obscures or obfuscates the layers below, such as the substrate 100.

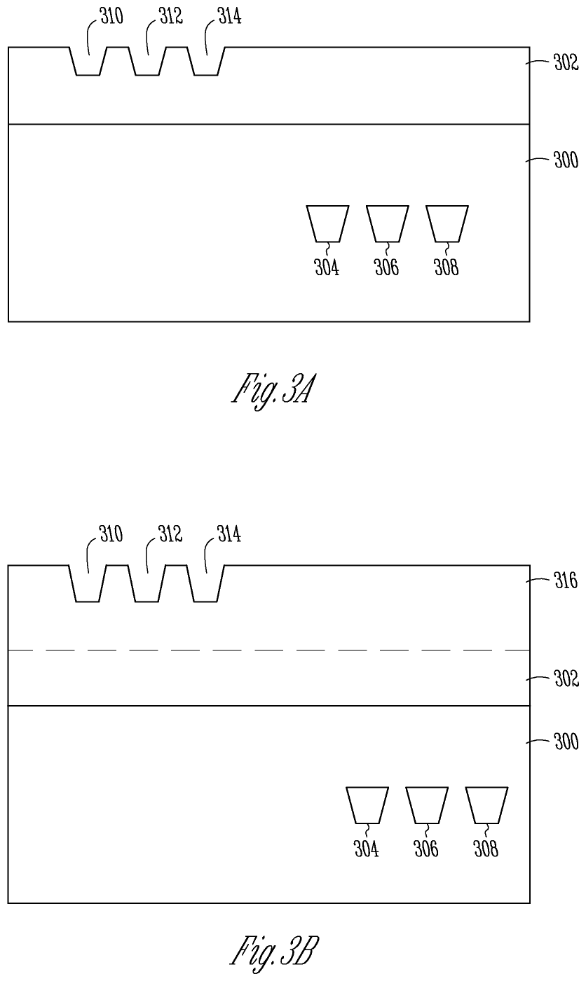

FIGS. 2A-2B illustrate generally an example of alignment marks buried in a hardmask layer 202 that is provided on a surface of a die. FIG. 2A illustrates a top view of a portion of a semiconductor device array (left) adjacent to a scribe line area (right). FIG. 2B illustrates a cross-section view of the same portion of the semiconductor from FIG. 2A. FIG. 2B illustrates generally various layers of the hardmask layer 202 and a resist layer 208. The alignment marks in the example of FIG. 2A and FIG. 2B can be disposed in a portion of the hardmask layer 202 that is above the device array, above the scribe line area, or above both areas.

In the example of FIGS. 2A and 2B, the die can include multiple layers, including a substrate layer 200, and a hardmask layer 202 that can comprise one or multiple layers. For example, the hardmask layer 202 can include a multiple-layer resist (MLR) such as can include a spun-on-carbon (SOC) layer 202A formed on the substrate layer 200 and an oxide-based material layer 202B disposed on the SOC layer 202A. While FIG. 2B illustrates two layers in the MLR stack, the stack can include as many layers as desired formed from any suitable material. In an example, alignment marks, such as first alignment mark 204 and a second alignment mark 206 can be buried, embedded, or deposited on or in at least a portion of the MLR or other portion of the hardmask layer 202. In an example, one or more of the alignment marks can be built into the MLR in dedicated etch and deposition steps, or can comprise a deposited film, or can be formed in the same deposition step(s) used to form the MLR stack. In an example, at least one of the first alignment mark 204 and the second alignment mark 206 corresponds to a location of one or more other features or structures that comprise the die or substrate layer 200. That is, at least one of the alignment marks can be provided at a known location relative to, for example, a circuit element or feature that is built in the die, or relative to features or structures in one or more other layers disposed on the die.

The layers of the MLR stack can comprise one or more masking layers. For example, the SOC layer 202A can be a first masking layer and the oxide-based material layer 202B can be a second masking layer. The second masking layer can be a patterned layer on the first masking layer configured to cover at least a portion of one or more of the alignment marks 204, 206, which can be aligned with a particular structure in or on the substrate layer 200.

A resist layer 208 can be formed on or applied to the hardmask layer 202, and the resist layer 208 can partially or completely cover the hardmask layer 202 and one or more of the first and second alignment marks 204 and 206. Hence, the alignment marks can be “buried” inside a portion of the die assembly and can be covered by the resist layer 208. When alignment marks are covered by the resist layer 208, the marks may not get etched during subsequent etch or exposure process steps, and accordingly features corresponding to the alignment marks may not transfer to the substrate layer 200 or to other features or components that comprise the substrate layer 200.

In an example, one or more of the layers in the hardmask layer 202 can be sacrificial layers that can be removed, for example during later stages of wafer processing. For example, the SOC layer 202A may be a sacrificial layer and the oxide-based material layer 202B can be an overlay layer that is aligned with the substrate layer 200 based on the alignment marks 204, 206.

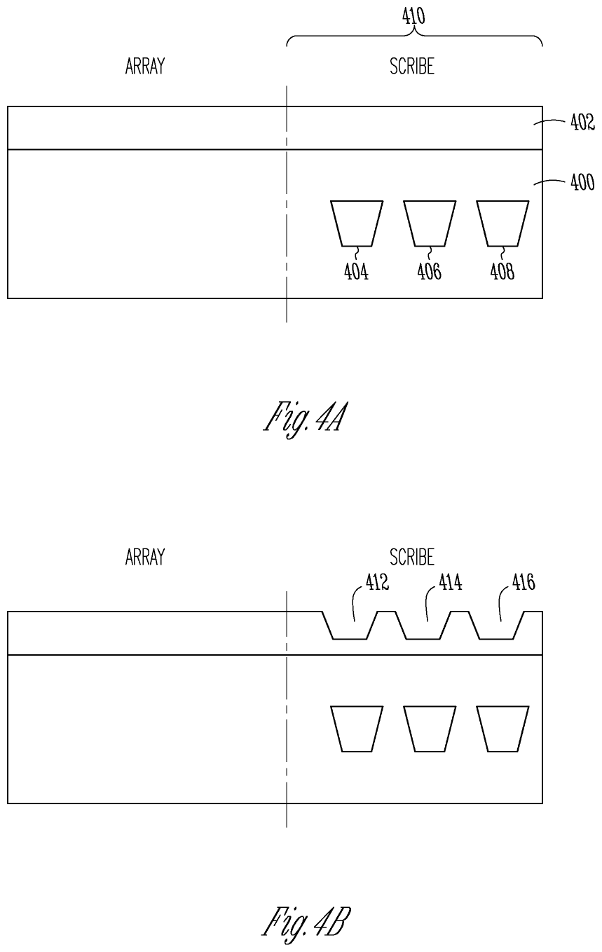

FIGS. 3A-3B illustrate generally an example that can include aligning topographical marks in a hardmask layer with reference marks (or other features) in a substrate layer. FIG. 3A illustrates a cross-section view of a substrate 300 with a first hardmask layer 302 on top of the substrate 300. The substrate 300 can include one or more reference features, such as a first reference feature 304, a second reference feature 306, and/or a third reference feature 308 (collectively “the embedded reference features”). The first hardmask layer 302 can have a first layer thickness or depth. In an example, the first hardmask layer 302 can comprise a material that is opaque or semi-opaque under particular wavelengths of light. In an example, the first layer thickness can be selected such that a signal, e.g., light, can pass through the first hardmask layer 302 and, accordingly, one or more of the embedded reference features can be detected. In an example, one or more alignment marks, such as a first alignment mark 310, a second alignment mark 312, and a third alignment mark 314 (collectively “the alignment marks”) can be formed in the first hardmask layer 302. The alignment marks can be provided at a specified location relative to the reference features such that information about a location of the alignment marks can be used to determine the location of the reference features.

FIG. 3B illustrates generally that a second hardmask layer 316 can be deposited on the first hardmask layer 302. The second hardmask layer 316 can have a second layer thickness or depth. Together, the first and second hardmask layers 302 and 316 can comprise a combined hardmask having a thickness corresponding to the sum of the first and second layer thicknesses. The alignment marks formed in the first hardmask layer 302 can be propagated up such that subsequent features or processes can be aligned with the embedded reference features. The thickness of the combined hardmask layers can be totally or completely opaque or nearly completely opaque such that a photoalignment signal is impeded by the hardmask and may not be used to locate the embedded reference features. However, information about the spatial relationship between the alignment marks (e.g., as propagated up through the hardmask layers) and the embedded reference features can be used for alignment of subsequent layers or processes. Thus, the alignment marks can be used to align and pattern any subsequent layers as the process is repeated until the wafer is fully fabricated.

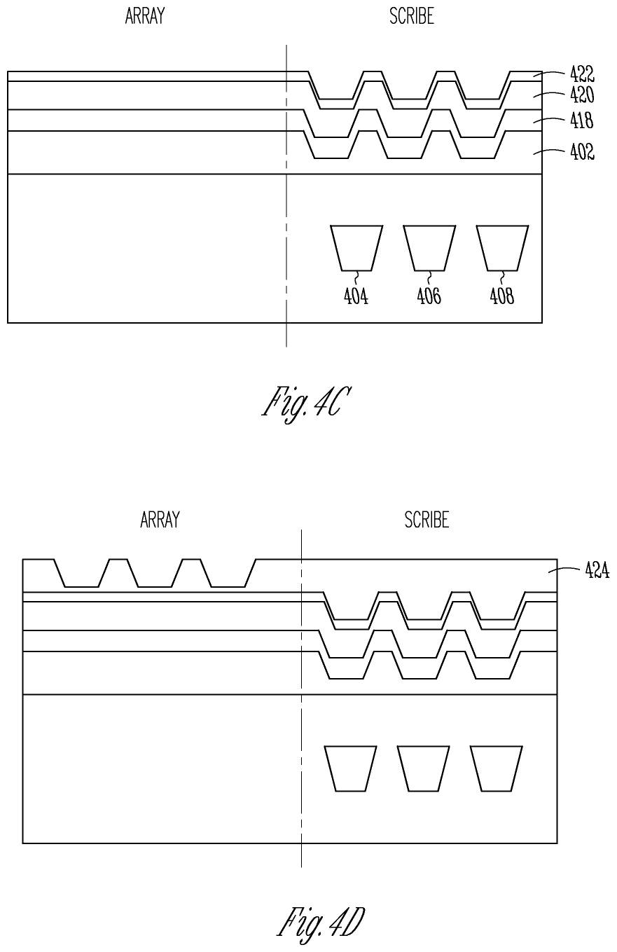

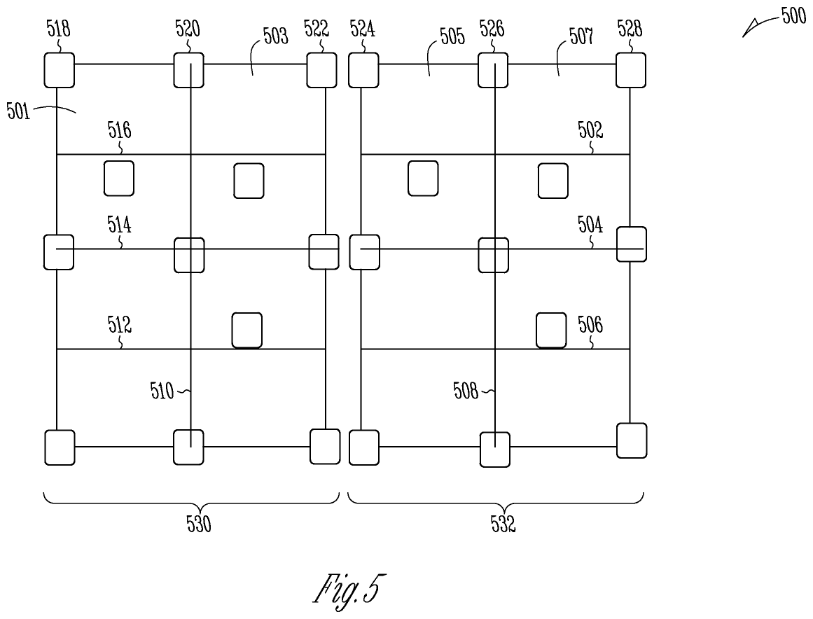

FIGS. 4A-4D illustrate generally an example of wafer fabrication using topographical marks and reference features in sacrificial areas of a die. FIG. 4A illustrates generally an example of a cross section of a substrate 400 including a sacrificial scribe area (e.g., corresponding to a scribe line 410) and a device array area. A first hardmask layer 402 can be provided over the scribe and array areas of the substrate 400. In an example, the substrate 400 can include reference features 404, 406, and 408, which can be reference marks and/or features that can correspond to, for example, passive or active circuit elements or other fiducial features. Similar to the process discussed herein and illustrated by FIGS. 3A and 3B, alignment marks 412, 414, and 416 can be patterned and etched into the first hardmask layer 402 as topographical marks, for example, in a known spatial relationship with the reference features 404, 406, 408.

FIG. 4C illustrates generally that additional layers, such as a first film layer 418, a second hardmask layer 420, and a second film layer 422, can be deposited on or over the first hardmask layer 402 and the alignment marks 412, 414, and 416 can propagate up through the various layers. Thus, the topographical features on an upper layer can correspond to and can be aligned with the reference features 404, 406, 408 via the alignment marks 412, 414, 416 in the first hardmask layer 402.

FIG. 4D illustrates generally that a resist layer 424 can be provided, for example, on an upper layer of the hardmask stack, such as on the second film layer 422. In an example, a photolithography process can be used to pattern the resist layer 424 based on the locations of the propagated-up alignment marks 412, 414, and 416. That is, at least a portion of the resist layer 424 can be patterned, including a portion spaced laterally apart from the reference features 404, 406, and 408 and/or spaced laterally apart from the alignment marks 412, 414, and 416. In an example, the first hardmask layer 402 and one or more of the additional layers such as first film layer 418, the second hardmask layer 420 and/or the second film layer 422 may be sacrificial layers that can be removed subsequent processing. Accordingly, the alignment marks 412, 414, and 416, and the propagated-up features corresponding to the alignment marks, can be removed, while the reference features 404, 406, 408 can remain a portion of the die.

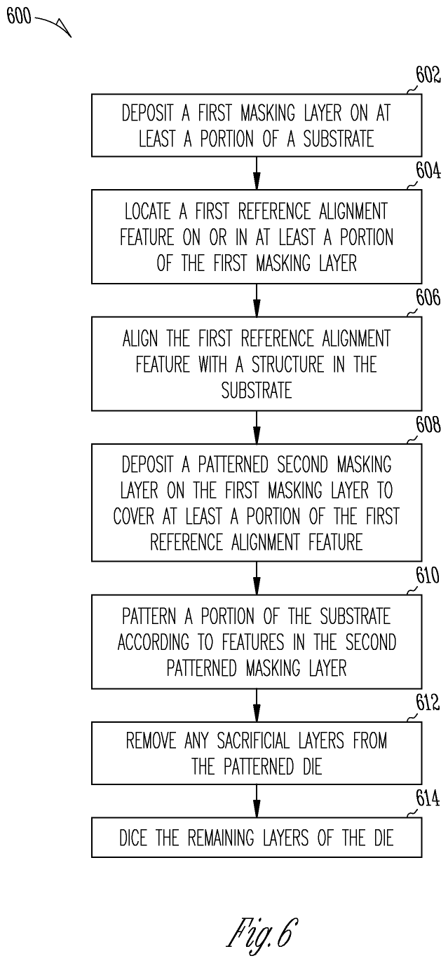

FIG. 5 illustrates generally an example of first and second portions 530 and 532 of a semiconductor assembly. Each of the portions can be divided into multiple fields or reticles. In the example of FIG. 5, each of the portions include eight separate fields or reticles such as fields 501, 503, 505, and 507 that are separated by scribe lines 502, 504, 506, 508, 510, 512, 514, and 516 (fewer than all of the fields are labeled in FIG. 5). In an example, each of the fields comprises a respective integrated circuit or other semiconductor-based assembly. In an example, the scribe lines 502, 504, 506, 508, 510, 512, 514, and 516 extend between the plurality of integrated circuits and provide the two-dimensional grid of each field. For example, the first portion 530 includes horizontal scribe lines 512, 514, and 516, and a vertical scribe line 510. Similarly, the second portion 532 can include horizontal scribe lines 502, 504, and 506, and a vertical scribe line 508.

The first and second portions 530 and 532 can include or use a plurality of alignment features, such as alignment marks that can be disposed in or on various portions of the semiconductor array. In an example, an alignment mark that comprises a portion of a sacrificial layer disposed on top of the semiconductor array can be referred to as an overlay mark.

In the example of FIG. 5, each of the first and second portions 530 and 532 of the semiconductor assembly includes a respective group of thirteen alignment marks disposed about the field. For example, each of the adjacent portions includes alignment marks at each of the four corners of the field, at a center of the field, at midpoints along the edges of each side of the field, and at other locations within or inside the field. For example, a first field of the first portion 530 includes a first top-left alignment mark 518, a first top-center alignment mark 520, and a first top-right alignment mark 522. A second field of the second portion 532 includes a second top-left alignment mark 524, a second top-center alignment mark 526, and a second top-right alignment mark 528. Additional or fewer alignment marks can similarly be used. Any one or more of the alignment marks can comprise a buried alignment mark or other reference feature that is disposed in or on the semiconductor array, for example, in or on a sacrificial layer disposed on the semiconductor array.

In the example of FIG. 5, a scribe line can intersect one or more of the alignment marks. For example, a first vertical scribe line 510 can intersect the first top-center alignment mark 520 and a second vertical scribe line 508 can intersect the second top-center alignment mark 526. Additionally, or alternatively, one or more of the marks may be located in a portion of one of the fields in which no scribe lines intersect, such as at an exterior corner of the two-dimensional grid, such as including overlay marks 518, 522, 525, and 528. In this example, the locations of the alignment marks are not limited by or restricted to locations of the scribe lines or a width of the scribe lines. Or, stated differently, the location of an alignment mark can be independent of a location or width of a scribe line.

The example fields and portions thereof that are illustrated in FIG. 5 can be fabricated using any of the processes discussed herein, for example, using sacrificial layers and sacrificial alignment marks and reference features. For example, the alignment marks shown in FIG. 5 can comprise a portion of a masking layer and/or can comprise a portion of a sacrificial hardmask deposited over a substrate. In some examples, the alignment marks shown in FIG. 5 can be formed or aligned with respect to other features that are in or on a die, such as alignment features in a hardmask or structures disposed in the substrate.

FIG. 6 illustrates generally an example of a method 600 that includes or uses one or more alignment features. At operation 602, the method 600 includes depositing a first masking layer on at least a portion of a substrate. The first masking layer can be an opaque or semi-opaque hardmask layer that can be formed from at least one of amorphous carbon, an organo siloxane material, SiN, SiON, TiN, tungsten, or a combination thereof. The first masking layer can be deposited on the substrate by chemical vapor deposition (CVD), physical vapor deposition (PVD), or spin coating (spin-on), or using another process or technique.

At operation 604, the method 600 can include providing a first reference alignment feature on or in at least a portion of the first masking layer. The first reference alignment feature can be deposited on the first masking layer as a portion of a new film deposition process (e.g., by depositing a layer of film on top of the first masking layer) or can be formed as a portion of the same process used to form the first masking layer (e.g., by etching the first masking layer), such that the first reference alignment feature is registered or aligned with respect to the structure. The first masking layer can be a sacrificial layer and the first reference alignment feature can be a sacrificial alignment mark, each of which can be removed in a later processing steps.

At operation 606, the method 600 can include depositing a patterned second masking layer on the first masking layer. In an example, the patterned second masking layer can cover at least a portion of the first reference alignment feature. The patterned second masking layer can be an overlay layer that is aligned with the substrate based on the first reference alignment feature. Thus, the patterned second masking layer can be aligned with the structure in the substrate by virtue of its alignment with the first reference alignment feature. In an example, the patterned second masking layer can include a resist material such as can be used to define a location of a structural feature for a memory device comprising a portion of the substrate.

In an example, the patterned second masking layer can include a second reference alignment feature that is spaced laterally apart from the first reference alignment feature. That is, the second reference alignment feature, which can be on a different layer than the first reference alignment feature, can be spaced vertically and horizontally away from the first reference alignment feature. The second reference alignment feature can include a topographical alignment feature formed on or etched into the second patterned masking layer. In an example, the first reference alignment feature can include a non-topographical feature that is embedded or buried into the first masking layer.

In an example, the patterned second masking layer can comprise at least one of amorphous carbon, an organo siloxane material, SiN, SiON, TiN, tungsten, a doped hardmask, or a combination thereof. Various other materials can similarly be used.

At operation 608, the method 600 can include patterning a portion of the substrate according to features in the second patterned masking layer. In an example, the pattern can be formed by etching or by other technique or process. At operation 610, the method 600 can include removing any sacrificial layers from the patterned die, including for example removing one or more of the alignment marks formed in the first or second masking layers. At operation 612, the method 600 can include dicing remaining layers of the die to form multiple dies or dice.

Some example benefits of the systems and methods described herein include more flexibility in the placement of alignment marks on or in a wafer. For example, using the techniques discussed herein, alignment marks may be unrestricted to scribe line areas and accordingly may not be subject to decreasing scribe width. In some examples, alignment marks can be placed in the die or substrate at locations that are more representative for overlay accuracy, for example, because the mark locations can correspond to locations of the circuit components or other features of the wafer or semiconductor. A further benefit can include increased flexibility in alignment mark shape or design, for example, because marks may not be restricted to specific patterns imposed by an array or scribe line pattern.

### Additional Notes & Examples

Various aspects of the present disclosure can help provide a solution to the alignment mark-related problems discussed herein. Example 1 can include a memory device comprising: a substrate; and a first alignment mark embedded in the substrate, wherein the first alignment mark is configured to be a reference for a patterned second masking layer, wherein the patterned second masking layer is different from a first masking layer on which the patterned second masking layer is deposited, and wherein the first masking layer comprises a second alignment mark.
In Example 2, the subject matter of Example 1 includes, wherein the first alignment mark is a topographical alignment mark.
In Example 3, the subject matter of Examples 1-2 includes, wherein the second alignment mark is a sacrificial alignment mark.
In Example 4, the subject matter of Examples 1-3 includes, wherein the first alignment mark is a topographical alignment mark, and wherein the first and second masking layers are sacrificial layers.
In Example 5, the subject matter of Examples 1˜4 includes, wherein the patterned second masking layer defines one or more locations of one or more structural features for the memory device comprising a portion of the substrate, and wherein the second alignment mark is a non-topographical alignment feature.
In Example 6, the subject matter of Examples 1-5 includes, wherein the patterned second masking layer is an overlay layer that is aligned with the substrate based on the first alignment mark.
In Example 7, the subject matter of Examples 1-6 includes, a scribe line intersecting the substrate, the first masking layer, the patterned second masking layer, and the first alignment mark.
In Example 8, the subject matter of Examples 1-7 includes, a scribe line intersecting the substrate, the first masking layer, and the patterned second masking layer, without intersecting the first alignment mark.
In Example 9, the subject matter of Examples 1-8 includes, wherein the first masking layer is an opaque hardmask layer that comprises at least one of amorphous carbon, an organo siloxane material, SiN, SiON, TiN, tungsten, a doped hardmask, or a combination thereof.
In Example 10, the subject matter of Examples 1-9 includes, wherein the second alignment mark comprises a film deposited on the patterned second masking layer using chemical vapor deposition, physical vapor deposition, or spin coating.
In Example 11, the subject matter of Examples 1-10 includes, wherein the patterned second masking layer comprises at least one of amorphous carbon, an organo siloxane material, SiN, SiON, TiN, tungsten, a doped hardmask, or a combination thereof.
Example 12 can include a semiconductor wafer comprising: a plurality of integrated circuits formed from a substrate and arranged in a two-dimensional grid; a plurality of first reference alignment features comprising a portion of a sacrificial hardmask disposed on the substrate; and a plurality of scribe lines extending between the plurality of integrated circuits to form the two-dimensional grid.
In Example 13, the subject matter of Example 12 includes, wherein the plurality of first reference alignment features are aligned with respect to other alignment features or structures that are disposed in the substrate.
In Example 14, the subject matter of Examples 12-13 includes, a patterned second masking layer deposited on the sacrificial hardmask and covering at least a portion of the plurality of first reference alignment features, and wherein the patterned second masking layer is an overlay layer that is aligned with structures in the substrate based on the plurality of first reference alignment features in the sacrificial hardmask.
In Example 15, the subject matter of Example 14 includes, wherein the plurality of first reference alignment features are sacrificial alignment marks and wherein the patterned second masking layer includes a plurality of topographical reference alignment features that are spaced laterally apart from the plurality of first reference alignment features, and wherein at least one of a particular reference alignment feature of the plurality of first reference alignment features or a particular topographical alignment feature of the plurality of topographical reference alignment features is located at an exterior corner of the two-dimensional grid.
Example 16 can include a method of semiconductor layer (e.g., overlay layer) alignment, the method comprising: depositing a first masking layer on at least a portion of a substrate; providing a first reference alignment feature on or in at least a portion of the first masking layer, wherein the first reference alignment feature is registered with respect to a particular structure in the substrate; and depositing a patterned second masking layer on the first masking layer and covering at least a portion of the first reference alignment feature.
In Example 17, the subject matter of Example 16 includes, wherein the first masking layer is an opaque hardmask layer that comprises at least one of amorphous carbon, an organo siloxane material, SiN, SiON, TiN, tungsten, or a combination thereof, wherein the first masking layer is a sacrificial layer, wherein the first reference alignment feature is a sacrificial alignment mark, and wherein the patterned second masking layer is an overlay layer that is aligned with the substrate based on the first reference alignment feature.
In Example 18, the subject matter of Examples 16-17 includes, etching a portion of the substrate according to features in the patterned second masking layer; and removing the first masking layer and the patterned second masking layer from the portion of the substrate.
In Example 19, the subject matter of Example 18 includes, wherein a scribe line intersects the substrate, the first masking layer, the patterned second masking layer, and the first reference alignment feature.
In Example 20, the subject matter of Examples 18-19 includes, wherein a scribe line intersects the substrate, the first masking layer, and the patterned second masking layer, without intersecting the first reference alignment feature.
Example 21 can include a semiconductor wafer comprising: a substrate; a first masking layer deposited on at least a portion of the substrate; a first reference alignment feature comprising a portion of the first masking layer; and a patterned second masking layer deposited on the first masking layer and covering at least a portion of the first reference alignment feature.
In Example 22, the subject matter of Example 21 includes, wherein the first masking layer is a sacrificial layer, and the first reference alignment feature is a sacrificial alignment mark.
In Example 23, the subject matter of Example 22 includes, wherein a location of the first reference alignment feature corresponds to a particular structure location in the substrate.
In Example 24, the subject matter of Example 23 includes, wherein the patterned second masking layer includes a second reference alignment feature that is spaced laterally apart from the first reference alignment feature.
Example 26 is an apparatus comprising means to implement any of Examples 1-24.

Each of these non-limiting numerical Examples can stand on its own, or can be combined in various permutations or combinations with one or more of the other Examples, or with other examples or features discussed elsewhere herein.

The above detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments may be used, such as by one of ordinary skill in the art upon reviewing the above description. The Abstract is to allow the reader to quickly ascertain the nature of the technical disclosure and is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the embodiments should be determined with reference to the appended claims, along with the full scope of equivalents to which such claims are entitled.

What is claimed is:

1. A memory device comprising:
a substrate; and
a first alignment mark embedded in the substrate, wherein the first alignment mark is configured to be a reference for a patterned second masking layer, wherein the patterned second masking layer is different from a first masking layer on which the patterned second masking layer is deposited, and wherein the first masking layer comprises a second alignment mark.

2. The memory device of claim 1, wherein the first alignment mark is a topographical alignment mark.

3. The memory device of claim 1, wherein the second alignment mark is a sacrificial alignment mark.

4. The memory device of claim 1, wherein the first alignment mark is a topographical alignment mark, and wherein the first and second masking layers are sacrificial layers.

5. The memory device of claim 1, wherein the patterned second masking layer defines one or more locations of one or more structural features for the memory device comprising a portion of the substrate, and wherein the second alignment mark is a non-topographical alignment feature.

6. The memory device of claim 1, wherein the patterned second masking layer is an overlay layer that is aligned with the substrate based on the first alignment mark.

7. The memory device of claim 1, comprising a scribe line intersecting the substrate, the first masking layer, the patterned second masking layer, and the first alignment mark.

8. The memory device of claim 1, comprising a scribe line intersecting the substrate, the first masking layer, and the patterned second masking layer, without intersecting the first alignment mark.

9. The memory device of claim 1, wherein the first masking layer is an opaque hardmask layer that comprises at least one of amorphous carbon, an organo siloxane material, SiN, SiON, TiN, tungsten, a doped hardmask, or a combination thereof.

10. The memory device of claim 1, wherein the second alignment mark comprises a film deposited on the substrate using chemical vapor deposition, physical vapor deposition, or spin coating.

11. The memory device of claim 1, wherein the patterned second masking layer comprises at least one of amorphous carbon, an organo siloxane material, SiN, SiON, TiN, tungsten, a doped hardmask, or a combination thereof.

12. A semiconductor wafer comprising:
a plurality of integrated circuits formed from a substrate and arranged in a two-dimensional grid;
a plurality of first reference alignment features comprising a portion of a sacrificial hardmask disposed on the substrate; and
a plurality of scribe lines extending between the plurality of integrated circuits to form the two-dimensional grid.

13. The semiconductor wafer of claim 12, wherein the plurality of first reference alignment features are aligned with respect to other alignment features or structures that are disposed in the substrate.

14. The semiconductor wafer of claim 12, further comprising:
a patterned second masking layer deposited on the sacrificial hardmask and covering at least a portion of the plurality of first reference alignment features, and wherein the patterned second masking layer is an overlay layer that is aligned with structures in the substrate based on the plurality of first reference alignment features in the sacrificial hardmask.

15. The semiconductor wafer of claim 14, wherein the plurality of first reference alignment features are sacrificial alignment marks and wherein the patterned second masking layer includes a plurality of topographical reference alignment features that are spaced laterally apart from the plurality of first reference alignment features, and wherein at least one of a particular reference alignment feature of the plurality of first reference alignment features or a particular topographical alignment feature of the plurality of topographical reference alignment features is located at an exterior corner of the two-dimensional grid.

16. A method of semiconductor overlay layer alignment, the method comprising:
depositing a first masking layer on at least a portion of a substrate;
providing a first reference alignment feature on or in at least a portion of the first masking layer, wherein the first reference alignment feature is registered with respect to a particular structure in the substrate; and
depositing a patterned second masking layer on the first masking layer and covering at least a portion of the first reference alignment feature.

17. The method of claim 16, wherein the first masking layer is an opaque hardmask layer that comprises at least one of amorphous carbon, an organo siloxane material, SiN, SiON, TiN, tungsten, or a combination thereof, wherein the first masking layer is a sacrificial layer, wherein the first reference alignment feature is a sacrificial alignment mark, and wherein the patterned second masking layer is an overlay layer that is aligned with the substrate based on the first reference alignment feature.

18. The method of claim 16, further comprising:
etching a portion of the substrate according to features in the patterned second masking layer; and
removing the first masking layer and the patterned second masking layer from the portion of the substrate.

19. The method of claim 18, wherein a scribe line intersects the substrate, the first masking layer, the patterned second masking layer, and the first reference alignment feature.

20. The method of claim 18, wherein a scribe line intersects the substrate, the first masking layer, and the patterned second masking layer, without intersecting the first reference alignment feature.
